(19) United States
(12) Patent Application Publication
(10) Pub. No.: US 2019/0294497 A1
(43) Pub. Date: Sep. 26, 2019

(54) METHOD OF IMPLEMENTING ERROR CORRECTION CODE USED BY MEMORY STORAGE APPARATUS AND MEMORY STORAGE APPARATUS USING THE SAME

(71) Applicant: Winbond Electronics Corp., Taichung City (TW)

(72) Inventors: Chuen-Der Lien, San Jose, CA (US); Ming-Huei Shieh, San Jose, CA (US); Chi-Shun Lin, San Jose, CA (US); Ngatik Cheung, San Jose, CA (US); Seow Fong Lim, San Jose, CA (US)

(73) Assignee: Winbond Electronics Corp., Taichung City (TW)

(21) Appl. No.: 16/034,365

(22) Filed: Jul. 13, 2018

Related U.S. Application Data
(63) Continuation-in-part of application No. 15/933,367, filed on Mar. 22, 2018.

(51) Int. Cl. G06F 11/10; G11C 11/56

(52) U.S. Cl. CPC G06F 11/1044; G11C 11/5642; G11C 11/5628

(57) ABSTRACT

The disclosure is directed to a method and an apparatus for implementing an error correcting code (ECC) used by a memory storage apparatus. In an aspect of the disclosure, the method would include not limited to: receiving a write command having a write address and a write data; reading an existing codeword comprising a predetermined bit sequence; encoding the write data into a new codeword based on a default ECC; flipping at least one bit of the new codeword based on a number of bits required to be changed from the existing codeword to the new codeword; writing the new codeword, wherein in response to every message bit of the new codeword to be flipped once, either an average or a maximum number of parity bits flips of the new codeword is minimized according to a modified ECC which is based on the default ECC.

### CROSS REFERENCE OF RELATED APPLICATION

This disclosure is a continuation-in-part and claims the priority benefit of U.S. application Ser. No. 15/933,367, filed on Mar. 22, 2018, now pending. The entirety of the above-mentioned patent application is hereby incorporated by reference herein and made a part of specification.

### BACKGROUND OF THE DISCLOSURE

### 1. Technical Field

This disclosure relates to a method of implementing an error correction code (ECC) which is used by memory storage apparatus and a memory storage apparatus using the same method.

### 2. Description of Related Art

Generally, data to be written to a rewritable memory device may be encoded into a codeword according to an error correcting codes. The codeword read from the rewritable memory device may also be processed by a corresponding decoding procedure to restore the data. The codeword, is usually a combination of the data itself and a parity data generated according to the Bose-Chaudhuri-Hocquenghem code, the hamming code, the hamming code with additional parity, the Reed-Solomon code, the Hsiao code, and etc.

To improve NVM write power, write time and cycling reliability, an approach and an on-chip ECC algorithm are required to achieve low power design and page write time reduction and improve device reliability.

### SUMMARY OF THE DISCLOSURE

Accordingly, the disclosure is directed to a method of implementing an error correction code (ECC) which is used by memory storage apparatus and a memory storage apparatus using the same method.

In an aspect, the disclosure is directed to a method of implementing an ECC used by a memory storage apparatus. The method would include not limited to: receiving a write command including a write address and a write data; reading an existing codeword comprising a predetermined bit sequence; encoding the write data into a new codeword based on a default ECC; flipping at least one bit of the new codeword based on a number of bits required to be changed from the existing codeword to the new codeword; and writing the new codeword, wherein in response to every message bit of the new codeword to be flipped once, either an average or a maximum number of parity bits flips of the new codeword is minimized according to a modified ECC which is based on the default ECC.

In an aspect, the disclosure is directed to a memory storage apparatus which would include not limited to: a connection interface, a memory array, and a memory control circuit includes comprises an ECC encoder and is coupled to the connection interface and the memory array. The memory control circuit would be configured for: receiving, through the connection interface, a write command including a write address and a write data; reading an existing codeword comprising a predetermined bit sequence; encoding the write data into a new codeword based on a default ECC; flipping at least one bit of the new codeword based on a number of bits required to be changed from the existing codeword to the new codeword; and writing the new codeword into the memory array, wherein in response to every message bit of the new codeword to be flipped once, either an average or a maximum number of parity bits flips of the new codeword is minimized according to a modified ECC which is based on the default ECC.

Based on the above, by adopting the method of implementing error correction code and the memory storage apparatus provided in the disclosure, as a result, the maximum number of bit flips of parity bits can be reduced and thus the write time and power consumption could be reduced.

To make the above features and advantages of the disclosure more comprehensible, several embodiments accompanied with drawings are described in detail as follows.

### BRIEF DESCRIPTION OF THE DRAWINGS

The accompanying drawings are included to provide a further understanding of the disclosure and are incorporated in and constitute a part of this specification. The drawings illustrate embodiments of the disclosure and, together with the description, serve to explain the principles of the disclosure.

FIG. 1 is a schematic block diagram illustrating a memory storage apparatus according to an embodiment of the disclosure.

FIG. 2 is a flowchart illustrating an encoding method of the Lien Code according to an embodiment of the disclosure.

FIG. 3 is a schematic diagram illustrating a Lien code modified by BCH (51, 33, 7), encoding method according to another embodiment of the disclosure.

FIG. 4 is a schematic diagram illustrating an encoding method of the Lien Code modified by BCH (51, 33, 7) according to another embodiment of the disclosure.

FIG. 5 is a schematic diagram illustrating an encoding method of the Lien Code modified by BCH (51, 33, 7) according to another embodiment of the disclosure.

FIG. 6 is a flowchart illustrating an encoding method of the Lien Code according to an embodiment of the disclosure.

FIG. 7 is a schematic diagram illustrating an encoding method of the Lien Code modified by BCH (52, 34, 7) according to another embodiment of the disclosure.

FIG. 8 is a flow chart which illustrates a proposed method of implementing an ECC used by memory storage apparatus in accordance with one of the exemplary embodiments of the disclosure.

FIG. 9A˜9D illustrates a Lien code example of using the proposed method of FIG. 8 in accordance with one of the exemplary embodiments of the disclosure.

FIG. 10A˜10D illustrates a Lien code example of using the proposed method of FIG. 8 in accordance with one of the exemplary embodiments of the disclosure.

FIG. 11A˜11D illustrates a Hsaio code example of using the proposed method of FIG. 8 in accordance with one of the exemplary embodiments of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

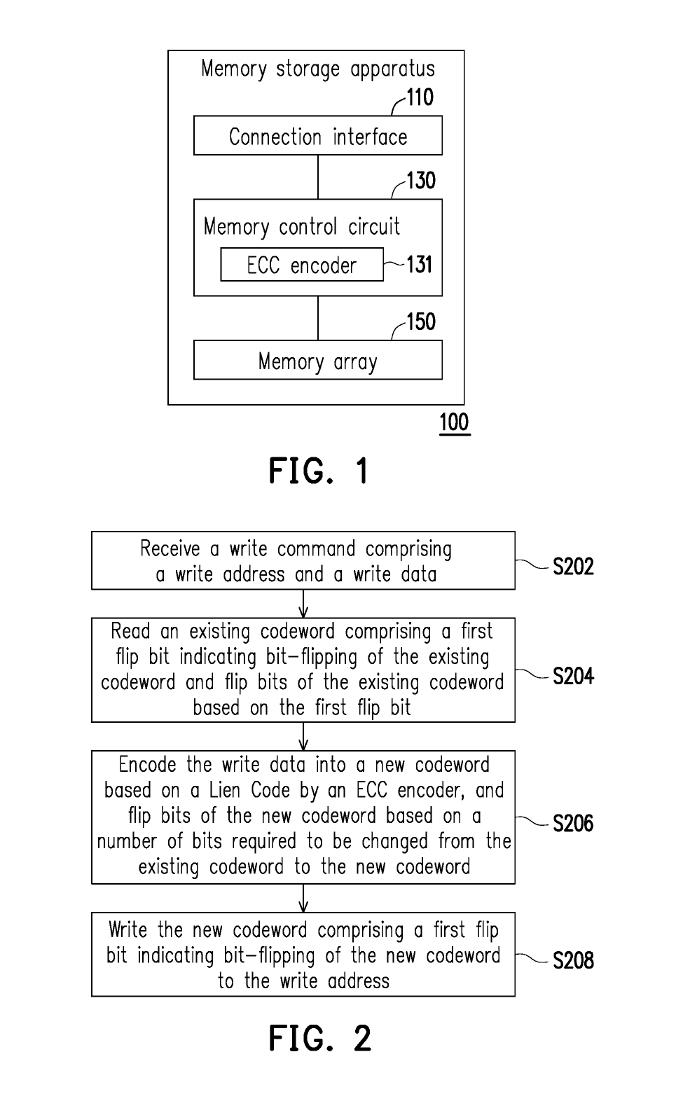

Referring to FIG. 1, the memory storage apparatus 100 includes a connection interface 110, a memory control circuit 130, and a memory array 150. In one embodiment, the memory storage apparatus 100 is a rewritable non-volatile memory, and the memory array 150 includes a plurality of rewritable non-volatile memory cells. The memory storage apparatus 100 may also be a resistive random-access memory (RRAM).

In one embodiment, the connection interface 110 is configured to couple to a host system (not shown) through a Serial Advanced Technology Attachment standard. In other embodiments, the connection interface 110 may comply with the Parallel Advanced Technology Attachment standard, the Institute of Electrical and Electronic Engineers 1394 standard, or other suitable standards, which is not limited in the disclosure. In one embodiment, the connection interface 110 may be packaged with the memory control circuit unit 130 in one chip or laid outside a chip having the memory control circuit unit 130.

The memory control circuit 130 is coupled to the connection interface 110 and the memory array 150 and is configured to execute a plurality of logic gates or control commands which are implemented in a hardware form or in a firmware form and perform operations such as data writing, reading or erasing in the memory array 150 according to the command of the host system.

In one embodiment, the memory storage apparatus 100 is a rewritable NVM or RRAM adopting a Lien ECC scheme, where the memory control circuit 130 further includes an ECC encoder 131 using a Lien Code for encoding the data received through the connection interface 110, so as to generate a codeword and write the same into the memory array 150. A feature of the Lien Code is that one's complement of a codeword generated by using the Lien Code is still another codeword generated by using the Lien Code.

The memory array 150 is coupled to the memory control circuit 130 including a plurality of memory cells (e.g., rewritable non-volatile memory cells). In one embodiment, the host system transmits a write command to the memory storage apparatus 100 for writing data thereto, and then the memory control circuit 130 encodes the write data into a codeword and stores the codeword in the memory array 150, in response to the write command.

FIG. 2 is a flowchart illustrating an encoding method of the Lien Code according to an embodiment of the disclosure. The encoding method of the Lien Code may be performed by the memory storage apparatus 100 of the embodiment of FIG. 1. Therefore, the encoding method will be illustrated by referring to the aforementioned memory storage apparatus 100 in the present embodiment.

Referring to FIG. 2, the memory control circuit 130 receives a write command comprising a write address and a write data through the connection interface 110 (step S202). In response to the received write command, the ECC encoder 131 of the memory control circuit 130 previously reads an existing codeword (step S204). In one embodiment, the existing codeword is a codeword previously stored in the write address, and in another embodiment, the existing codeword is a codeword with a predefined data pattern (e.g., 000000 . . . , or FFFFFF . . . ), which is not limited herein.

Meanwhile, the ECC encoder 131 encodes the write data into a new codeword based on a Lien Code and flips a plurality of bits of the new codeword based on a number of bits required to be changed from the existing codeword to the new codeword (step S206). To be specific, the ECC encoder 131 may calculate a parity data of the write data based on the Lien Code, and combine the parity data and the write data to generate the new codeword in the step S206. Then, the ECC encoder 131 compares a plurality of bits of the encoded new codeword with a plurality of bits of the read existing codeword to determine the number of bits required to be changed from the existing codeword to the new codeword and determines whether the determined number of bits is over a predetermined threshold. It is noted that one's complement of the encoded new codeword is also a codeword.

In some embodiments, the predetermined threshold is half of the number of codeword bits, which is not limited herein. If the determined number of bits is determined as over the predetermined threshold, the ECC encoder 131 flips the plurality of bits in the encoded new codeword and generates a first flip bit indicating bit-flipping of the new codeword in the new codeword. In some embodiments, the ECC encoder 131 generates the first flip bit with a value 0 for indicating that the bits of the codeword to be written are all flipped. On the other hand, if the determined number of bits is determined as lower than the predetermined threshold, the ECC encoder 131 does not perform the bit-flipping on the bits of the encoded codeword. It is noted that if the predetermined threshold is equal to a half of the number of codeword bits and the determined number of bits is determined as equal to the predetermined threshold, that is, the number of bits to be changed is the same as a number of bits not to be changed, the ECC encoder 131 also does not perform the bit-flipping on the bits of the encoded new codeword.

Finally, the ECC encoder 131 writes the new codeword comprising the first flip bit to the write address (step S208).

Based on the above, since the number of bits changed from the existing codeword to the new codeword is reduced to be less than a half of the number of codeword bits by selectively flipping the bits of the codeword to be written, the write time and power can be reduced and the reliability can be improved.

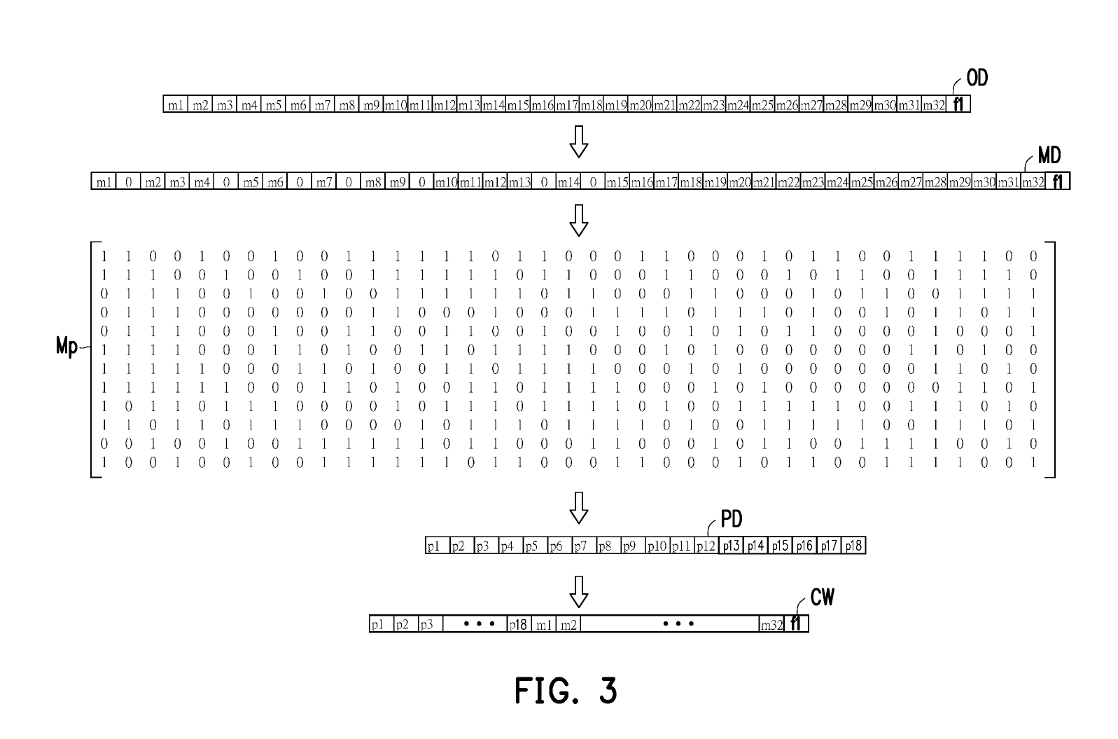

For example, FIG. 3 is a schematic diagram illustrating a Lien code modified by BCH (51, 33, 7), encoding method according to another embodiment of the disclosure.

Referring to FIG. 3, based on the Lien Code modified by BCH (51, 33, 7), the ECC encoder 131 encodes a 33-bit data OD including 32 data bits m1 to m32 and one flip bit fl into a 51-bit codeword CW, and the matrix Mp is an 18*41 matrix used for calculating an 18-bit parity data PD of the 33-bit data OD. To be specific, the 33-bit data OD is expanded into a 41-bit data MD by inserting eight bits of “0” to the 33-bit data OD in advance, so as to generate the 41-bit data MD with the 8^{th}, 10^{th}, 14^{th}, 15^{th}, 16^{th} , 23^{th}, 28^{th} and 30^{th} bits are the inserted “0”. The 41-bit data MD may be written in a one-column vector with 41 elements m1 to m32 and f1 and eight zeros as shown in FIG. 3, where the 33 elements m1 to m32 and f1 represent 33 bits of the data OD. The 41-bit data MD is then multiplied by the matrix Mp, so as to obtain a one-column vector with 18 elements p1 to p18 each represents one bit of the 18-bit parity data PD. Then, the ECC encoder 131 attaches the 33-bit data OD to the 18-bit parity bit data PD to generate the 51-bit codeword CW.

Based on the encoding method using Lien code described above, the new codeword comprising the flip bit is generated from the write data by the ECC encoder 131. It is noted, in one embodiment, the flip bit of the newly encoded codeword is deter mined to minimize the number of bits changed from the existing codeword read from the write address to the new codeword, and in another embodiment, the flip bit is determined to minimize a number of bits changed from the existing codeword with a predefined data pattern to the new codeword. Exemplary embodiments are given below for further illustration.

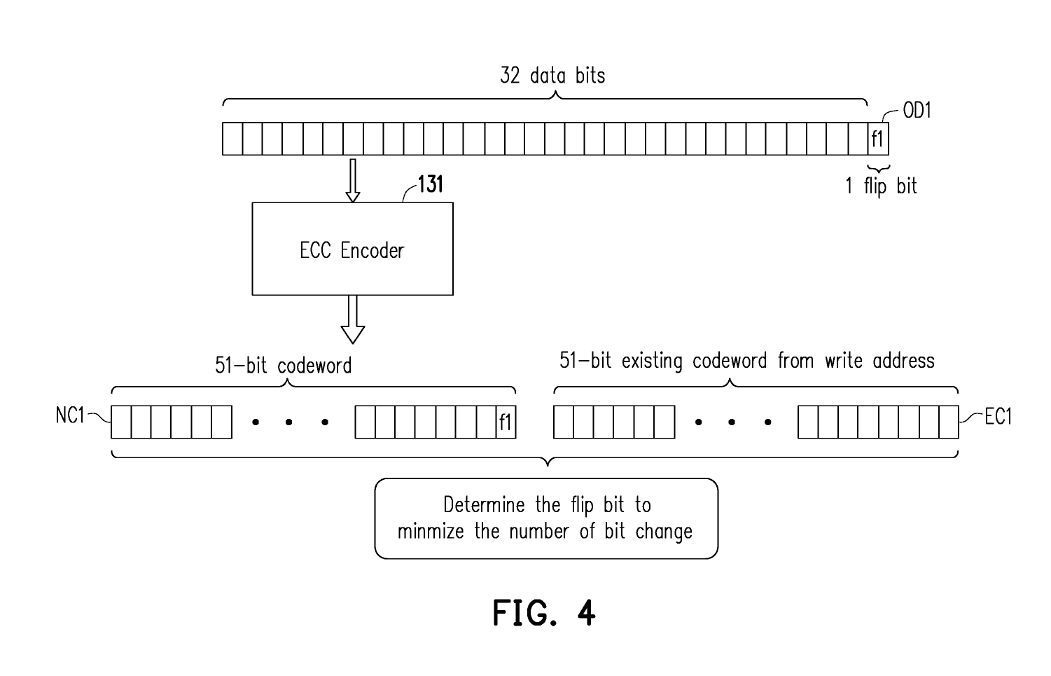

FIG. 4 is a schematic diagram illustrating an encoding method of the Lien Code modified by BCH (51, 33, 7) according to another embodiment of the disclosure. Referring to FIG. 4, when receiving a write data OD1 comprising 32 data bits and one flip bit, the ECC encoder 131 encodes the write data OD1 into a 51-bit new codeword NC1 by using the ECC lien Code as described in the embodiment of FIG. 3. The ECC encoder 131 also reads out a 51-bit existing codeword EC1 from the write address and previously flips bits of the existing codeword EC1 based on the flip bit included in the existing codeword EC1. Then, the ECC encoder 131 compares a plurality of bits of the new codeword NC1 with a plurality of bits of the existing codeword EC1 to determine the flip bit of the codeword NC1 to minimize the number of bits changed from the existing codeword EC1 to the new codeword NC1. Finally, the ECC encoder 131 flips the bits of the new codeword NC1 based on the determined flip bit, updates the flip bit in the flipped new codeword NC1, and writes the new codeword NC1 comprising the flip bit to the write address.

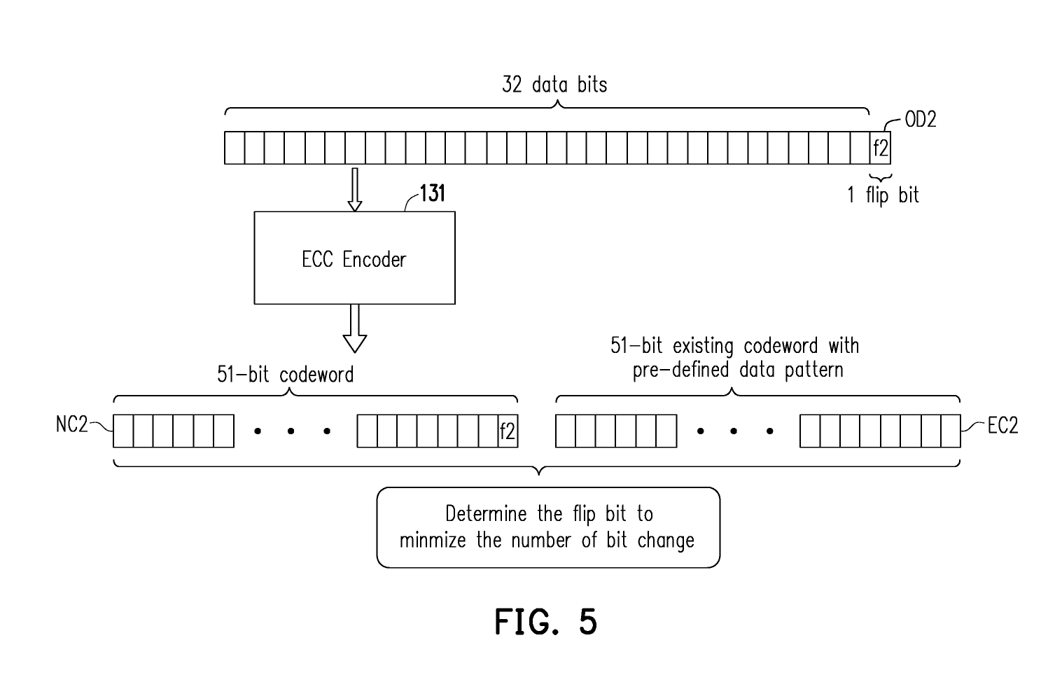

On the other hand, FIG. 5 is a schematic diagram illustrating an encoding method of the Lien Code modified by BCH (51, 33, 7) according to another embodiment of the disclosure. Referring to FIG. 5, when receiving a write data OD2 comprising 32 data bits and one flip bit, the ECC encoder 131 encodes the write data OD2 into a 51-bit new codeword NC2 by using the ECC lien Code as described in the embodiment of FIG. 3. The ECC encoder 131 also reads out a 51-bit existing codeword EC2 with a predefined data pattern such as 000000 . . . . Then, the ECC encoder 131 compares a plurality of bits of the new codeword NC2 with a plurality of bits of the existing codeword EC2 to determine the flip bit of the codeword NC2 to minimize the number of bits changed from the existing codeword EC2 to the new codeword NC2. Finally, the ECC encoder 131 flips the bits of the new codeword NC2 based on the determined flip bit, updates the flip bit in the flipped new codeword NC2, and writes the new codeword NC2 comprising the flip bit to the write address.

It is noted, in some embodiments, in addition to minimizing the bit change in writing, the flip bit may be further used to minimize flipping of selected bits such as parity bits so as to improve bit write endurance, but the disclosure is not limited thereto.

To further reduce write time and power, in some embodiments, multiple flip bits are adopted to respectively indicate the bit-flipping of different portions of the codeword, and in some embodiments, the flip bits are also contained in different portions of the codeword, which is not limited herein. In one embodiment, the flip bits include a first flip bit contained in one of a plurality of even bits of the codeword for indicating the bit-flipping of the even bits and a second flip bit contained in one of a plurality of odd bits of the codeword for indicating the bit-flipping of the odd bits.

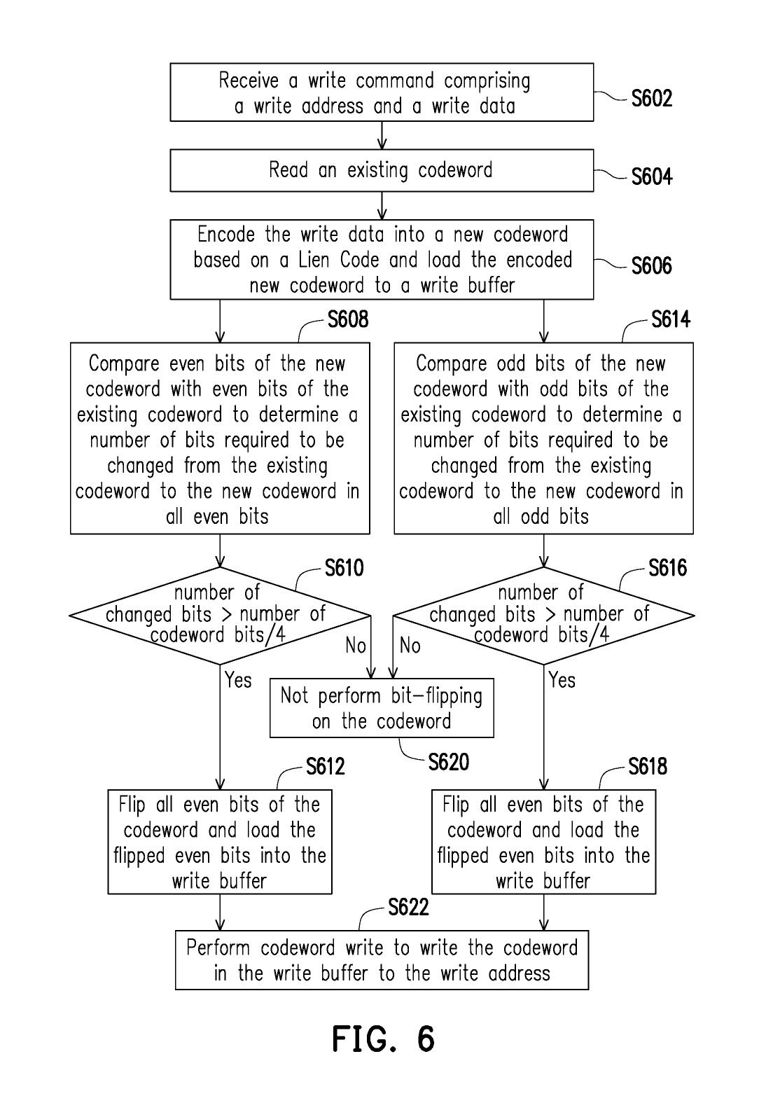

FIG. 6 is a flowchart illustrating an encoding method of the Lien Code according to an embodiment of the disclosure. The encoding method of the Lien Code may be performed by the memory storage apparatus 100 of the embodiment of FIG. 1. Therefore, the encoding method will be illustrated by referring to the aforementioned memory storage apparatus 100 in the present embodiment.

Referring to FIG. 6, the memory control circuit 130 receives a write command comprising a write address and a write data (step S602). In response to the received write command, the ECC encoder 131 of the memory control circuit 130 previously reads an existing codeword (step S604). In one embodiment, the existing codeword is a codeword previously stored in the write address, and in another embodiment, the existing codeword is a codeword with a predefined data pattern (e.g., 000000 . . . , or FFFFFF . . . ), which is not limited herein.

Meanwhile, the ECC encoder 131 encodes the write data into a new codeword based on a Lien Code without flipping the bits of the new codeword and loads the encoded new codeword to a write buffer (step S606), and then the ECC encoder 131 executes steps S608 and S614 in parallel or in a sequence. It is noted that one's complement of the encoded new codeword is also a codeword.

In step S608, the ECC encoder 131 compares even bits of the new codeword with even bits of the existing codeword to determine a number of bits required to be changed from the existing codeword to the new codeword in all even bits, and then determines whether the determined number of changed bits is over a quarter of a number of codeword bits (step S610). If yes, the ECC encoder 131 flips all even bits of the codeword and loads the flipped even bits into the write buffer (step S612).

Similarly, in step S614, the ECC encoder 131 compares odd bits of the new codeword with odd bits of the existing codeword to determine a number of bits required to be changed from the existing codeword to the new codeword in all odd bits, and then determines whether the determined number of changed bits is over a quarter of a number of codeword bits (step S616). If yes, the ECC encoder 131 flips all odd bits of the codeword and loads the flipped odd bits into the write buffer (step S618).

It is noted, in the steps S610 and S616, if the determination result is no, then the ECC encoder 131 does not perform bit-flipping on the codeword (step S620) and therefore there is no change in the write buffer. It is noted that, in each portion of the even bits and the odd bits, the ECC encoder 131 does not perform bit-flipping if the number of bits to be changed is the same as a number of bits not to be changed.

Finally, the ECC encoder 131 performs codeword write to write the codeword in the write buffer to the write address (step S622).

Based on the above, since the number of bits changed from the existing codeword to the new codeword is reduced by selectively and separately flipping the even bits and the odd bits of the codeword to be written, the write time and power can be further reduced and the reliability can be further improved.

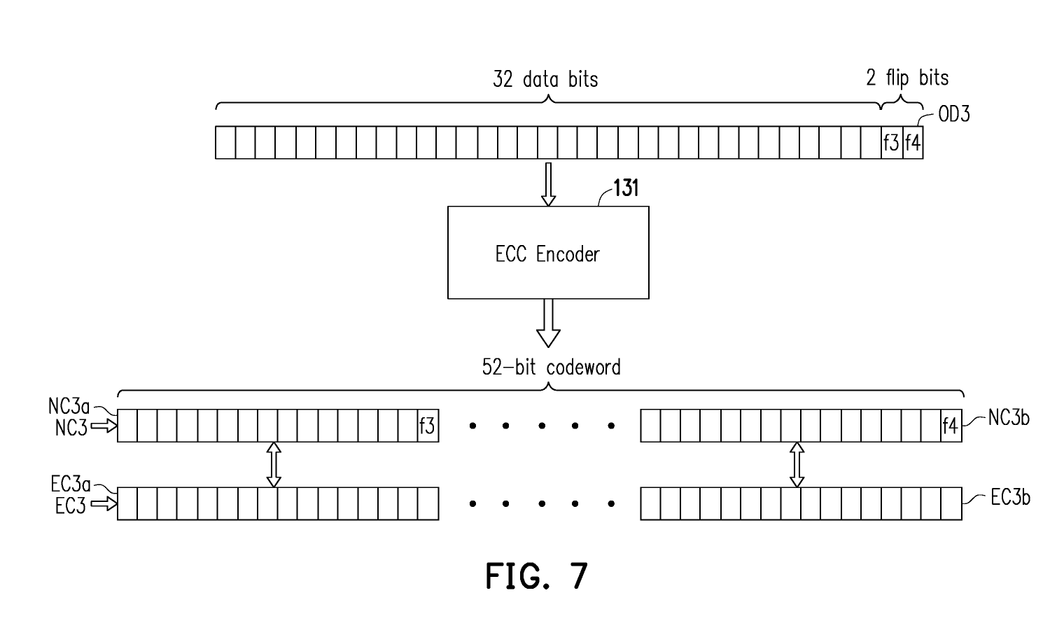

For example, FIG. 7 is a schematic diagram illustrating an encoding method of the Lien Code modified by BCH (52, 34, 7) according to another embodiment of the disclosure. Referring to FIG. 7, when receiving a write data OD3 comprising 32 data bits and two flip bits 13 and f4, the ECC encoder 131 encodes the write data OD3 into a 52-bit new codeword NC3 by using the ECC lien Code. It is noted that, in some embodiments, the flip bits f3 and f4 individually control flipping of all even data bits and all odd data bits in the write data OD3 and accordingly, before encoding the write data OD3, the ECC encoder 131 may read the flip bits 13 and f4 and flipping even data bits and/or odd data bits in the write data OD3 based on the flip bits f3 and f4.

In some embodiments, in response to receiving the write command, the ECC encoder 131 also reads out a 52-bit existing codeword EC including two flip bits and previously flips even codeword bits and/or odd codeword bits in the existing codeword EC based on the flip bits.

Then, the ECC encoder 131 compares a plurality of even bits NC3a of the new codeword NC3 with a plurality of even bits EC3a of the existing codeword EC3 to determine the first flip bit f3 of the codeword NC3 to minimize the number of bits changed from the existing codeword EC3 to the new codeword NC3 in all even bits. Meanwhile, the ECC encoder 131 also compares a plurality of odd bits NC3b of the new codeword NC3 with a plurality of odd bits EC3a of the existing codeword EC to determine the second flip bit f4 of the codeword NC3 to minimize the number of bits changed from the existing codeword EC3 to the new codeword NC3 in all odd bits. The flip bits f3 and f4 determined above individually control flipping of all even codeword bits and all odd codeword bits in the codeword NC3. Further, it is noted that one's complement of any portion (i.e. even bits or odd bits) of the encoded new codeword is also a codeword.

Finally, the ECC encoder 131 flips the even bits NC3a of the new codeword NC3 based on the determined first flip bit f3, flips the odd bits NC3b of the new codeword NC3 based on the determined second flip bit f4, updates the first flip bit f3 and the second flip bit f4 in the flipped new codeword NC3, and writes the new codeword NC3 comprising the flip bits f3 and f4 to the write address.

In the aforesaid embodiments, the flip bits are determined to minimize the number of even bits and odd bits changed from the existing codeword to the encoded codeword. However, in some embodiments, the flip bits may be determined to minimize the number of bits changed in parity bits in the first portion or second portion containing the flip bit, but the disclosure is not limited thereto.

In summary, in the encoding method and the memory storage apparatus provided in the disclosure, a Lien ECC scheme based on a Lien Code is introduced to implement a NVM flip bit write function with BCH ECC algorithm, in which one or more flip bits are adopted to control data bits flipping or codeword bits flipping on different portions of the data bits or codeword bits. As a result, the number of bit change in writing can be reduced and write time and power can be reduced.

In an aspect, the disclosure is directed to a method of implementing an error correction code (ECC) which is used by memory storage apparatus the maximum number of bit flips of parity bits can be reduced and thus the write time and power consumption could be reduced.

For a resistive random-access memory device that uses an ECC, the multiple byte write operations in an ECC codeword would likely always make parity bits to have more write cycles than message bits. For example, in a ECC BCH(50,32,7) codeword which has 4 bytes of message bits and 18 parity bits, if 4 byte write individually to write 1 cycle on message, the 18 parity bits could have 4 cycles in a worse case. The ECC which adopts a Lien code or other codes could be modified to provide a solution to minimize the parity bits cycling times during byte write operations.

Thus, in order to enhance the ECC parity bits endurance during a multiple byte write in a codeword, the disclosure proposes a modified ECC scheme which would minimize the maximum number of parity bits' flips that is in response to any bit flip of the message bits once, to minimize the average number of parity bits' flips that is in response to any bit flip of the message bits once, or to minimize the average number of parity bits' flips that is in response to any byte flip of the message bits once. Parity bits could be added in a way that minimizes the maximum number of the average number of parity bit flips if every message bit flips once. The maximum or average number of parity bits' flips could be minimized by rearranging the sequence of bits within the codeword in a trial and error manner.

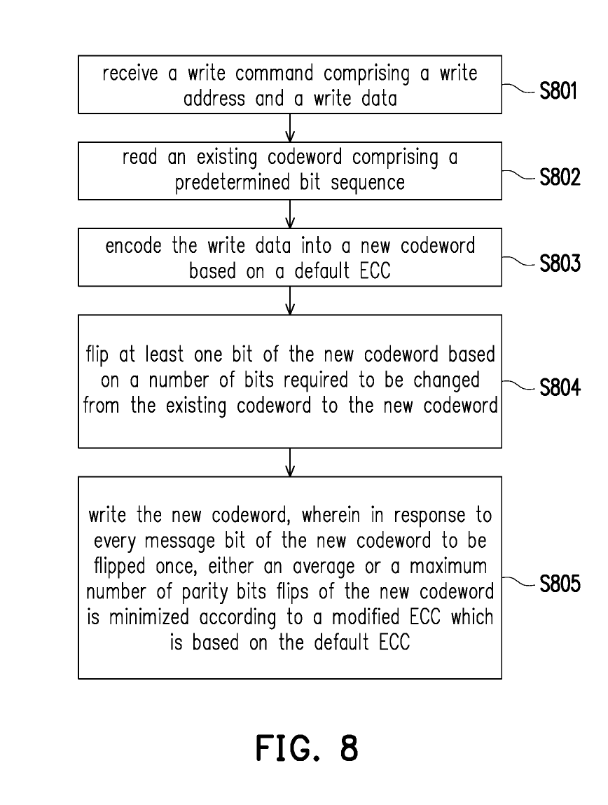

FIG. 8 is a flow chart which illustrates a proposed method of implementing an ECC used by memory storage apparatus in accordance with one of the exemplary embodiments of the disclosure. In step S801, the memory storage apparatus 100 would receive, from the connection interface 110, a write command which may include a write address and a write data. In step S802, the memory control circuit 130 of the memory storage apparatus 100 may read an existing codeword which includes a predetermined bit sequence. In step S803, the ECC encoder 131 of the memory control circuit 130 may encode the write data into a new codeword based on a default ECC. In step S804, the memory control circuit 130 may flip at least one bit of the new codeword based on a number of bits required to be changed from the existing codeword to the new codeword In step S805, the memory control circuit 130 may write the new codeword into the memory array 150. In response to every message bit of the new codeword to be flipped once, either an average or a maximum number of parity bits flips of the new codeword is minimized according to a modified ECC which is based on the default ECC.

In one exemplary embodiment, the above described modified ECC could be modified from a Bose-Chaudhuri-Hocquenghem (BCH) code, a Hamming code SECDED, Hamming code, a Hsiao code, a Reed-Solomon code, or a Lien code.

In one exemplary embodiment, the above described modified ECC could be used in a counter. In one exemplary embodiment, the above described counter could be a Gray counter.

In one exemplary embodiment, in response to every message bit of the new codeword to be flipped once, either an average or a maximum number of parity bits flips of the new codeword is minimized according to a modified ECC which is based on the default ECC by adding parity bits to the default ECC as the modified ECC so that either an average or a maximum number of parity bits flips of the new codeword is minimized.

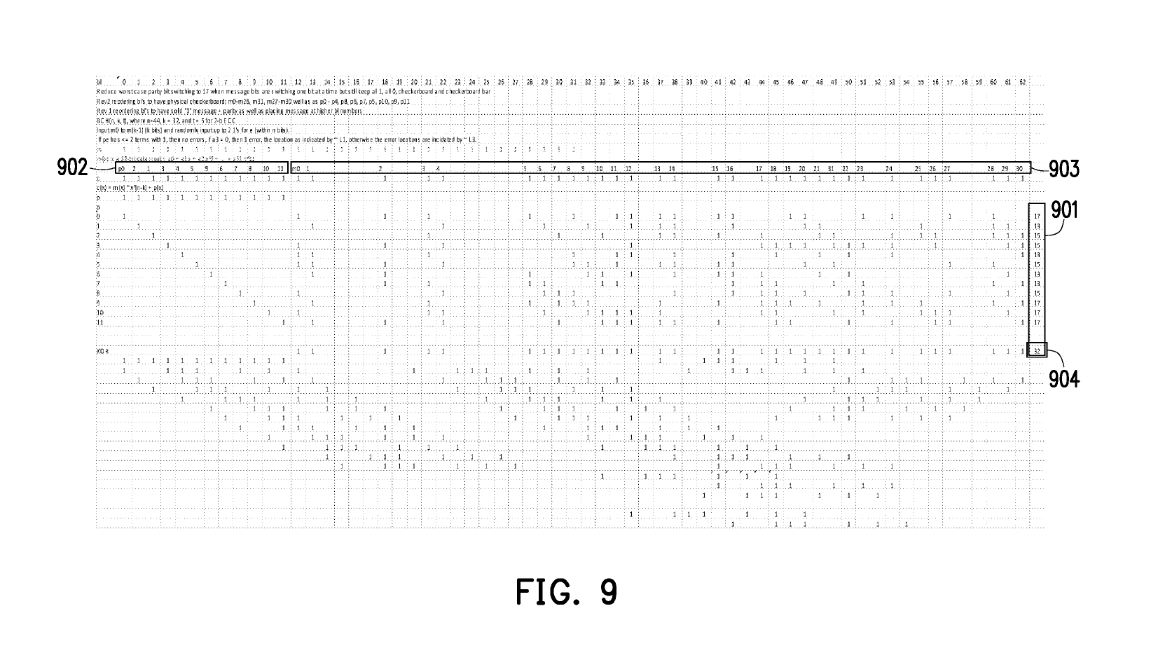

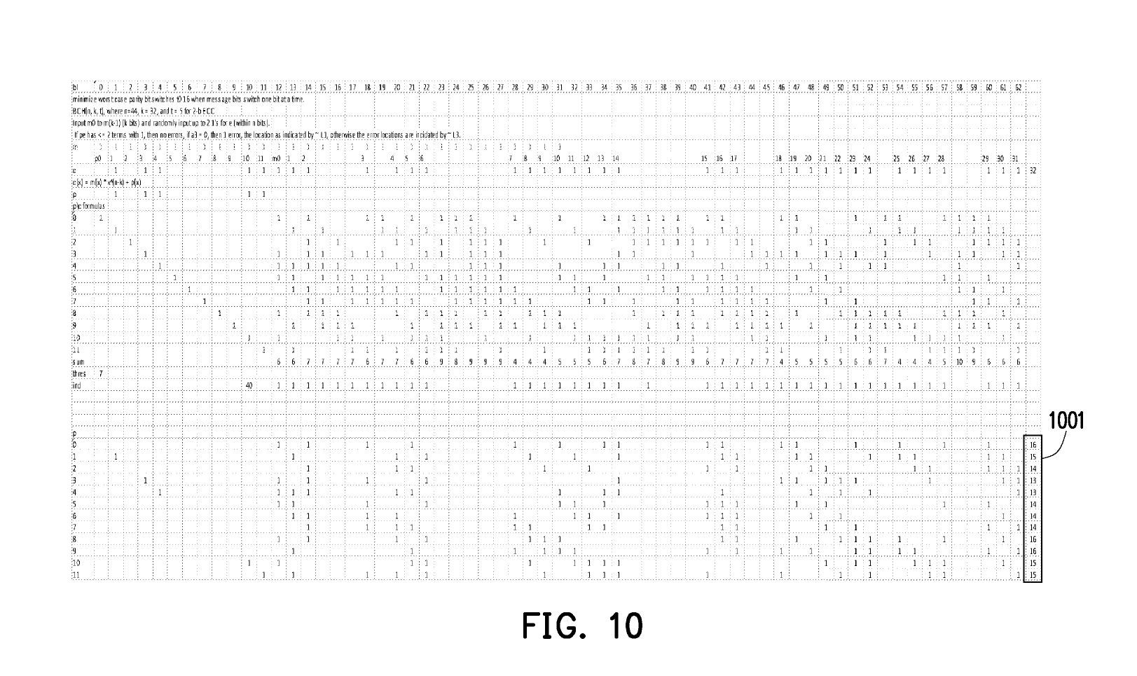

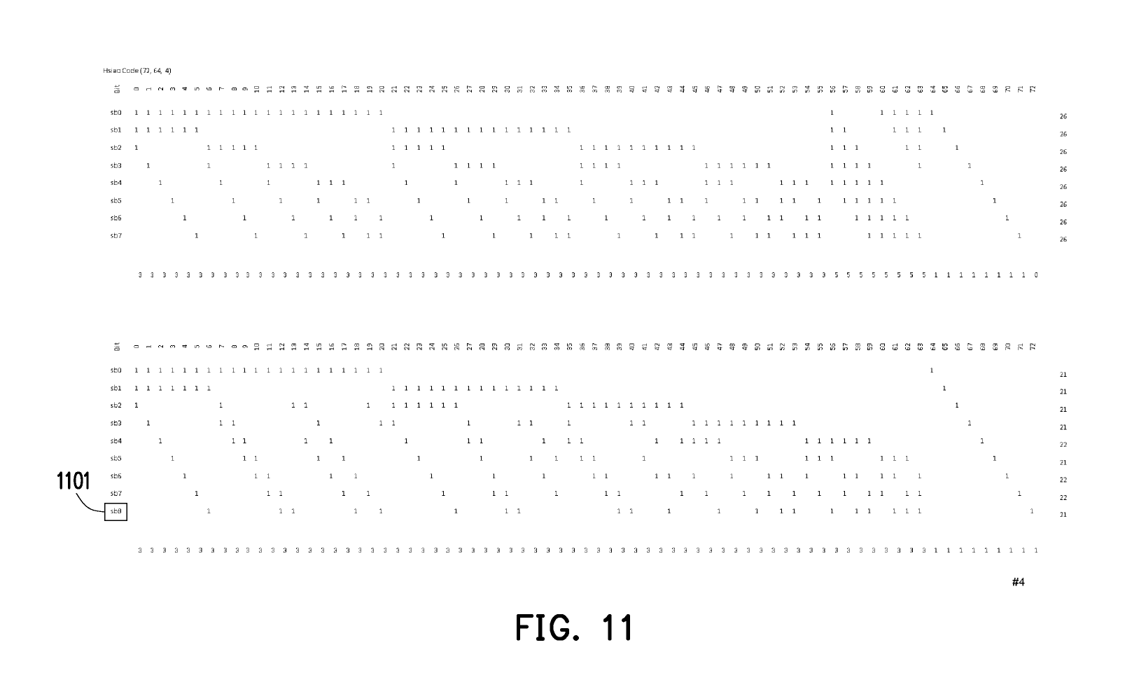

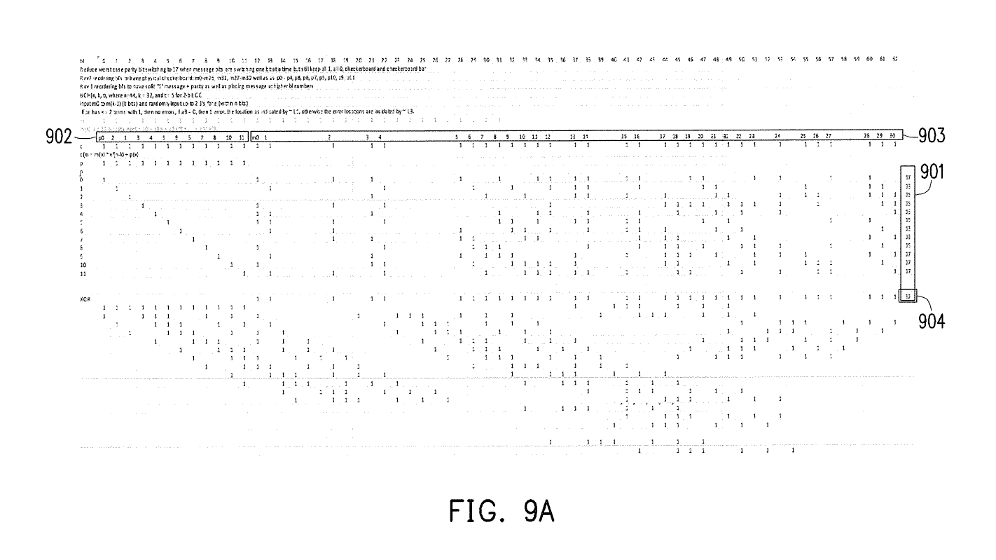

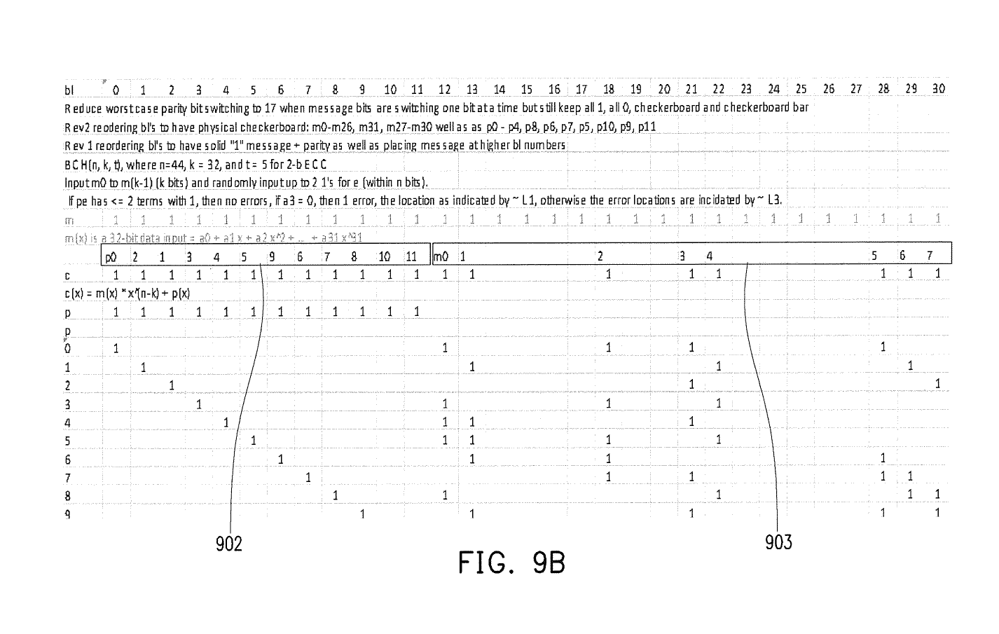

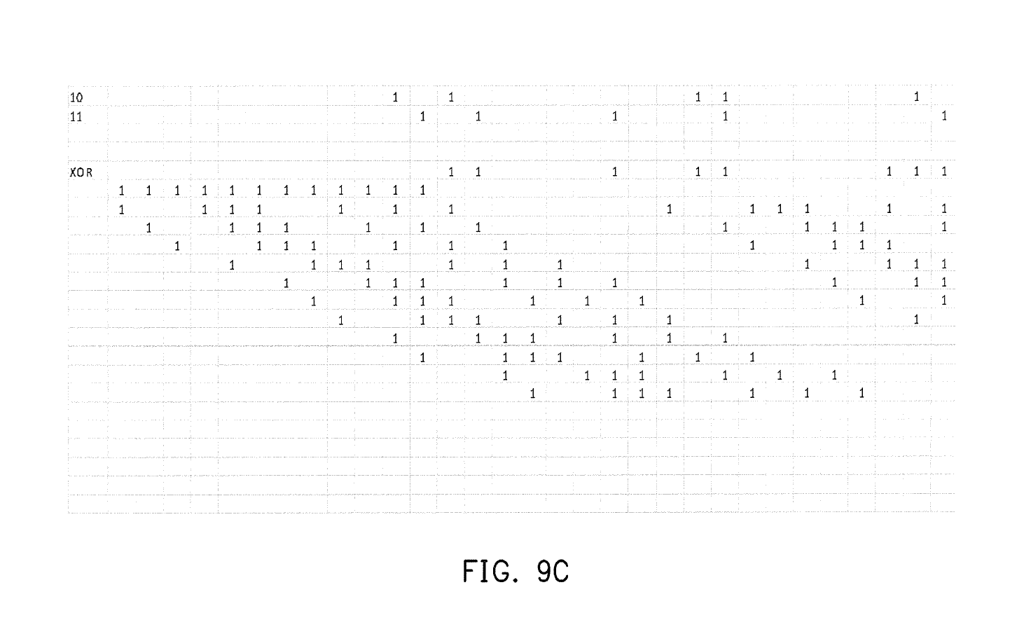

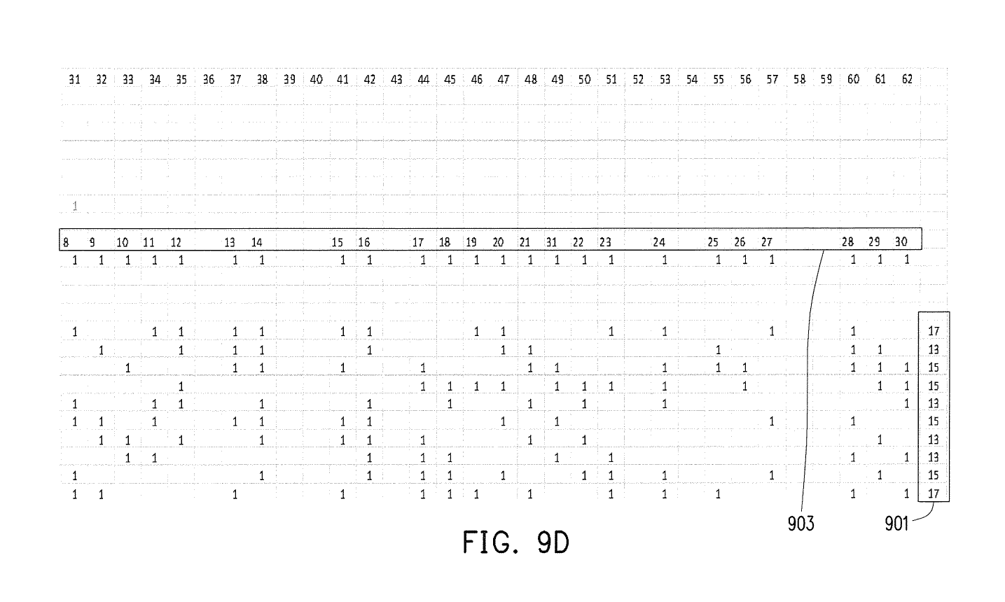

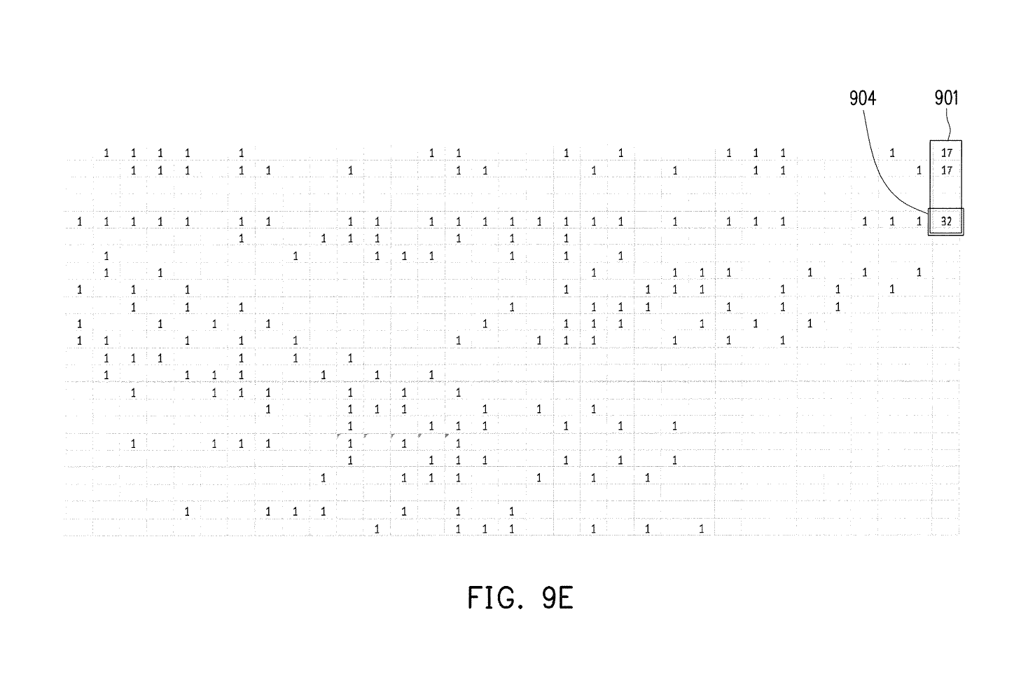

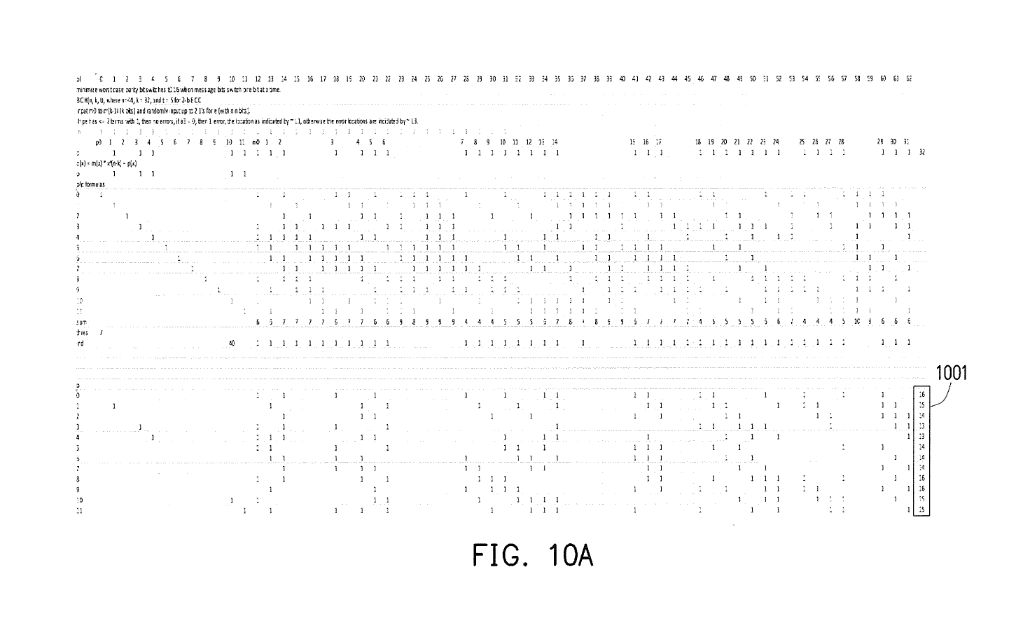

FIG. 9A˜9D is a chart which illustrates a Lien code example of using the proposed method of FIG. 8 in accordance with one of the exemplary embodiments of the disclosure. In this example, the Lien Code modified BCH(n, k, t) is used where n=44, k=32, and t=5 for 2-b ECC. The parity bits flips 902 and message bits flips 903 are mark as ‘1’ in this chart. In this example, the Lien Code modified BCH(n, k, t) is shown to be able to reduce the parity bit flips 901 among which 17 is the worst case when message bits 902 are flipping one bit at a time but still keep all 1's, all 0's, adapting a checkerboard pattern, or adapting an inverse checkerboard pattern. The bit flips of the entire set 904 is shown to be minimized as 32. In one exemplary embodiment, the encoded codeword could be reordered to have a checkerboard pattern in the manner of the message bits in a sequence of m0-m26, m31, m27-m30 as well as parity bits in a sequence of p0-p4, p8, p6, p7, p5, p10, p9, p11. In another exemplary embodiment, the parity bit flips could be minimized by having the encoded codeword be reordered to have solid “1” in the message bits and/or parity bits as well as by placing some or all message bits at higher bit numbers of the codeword.

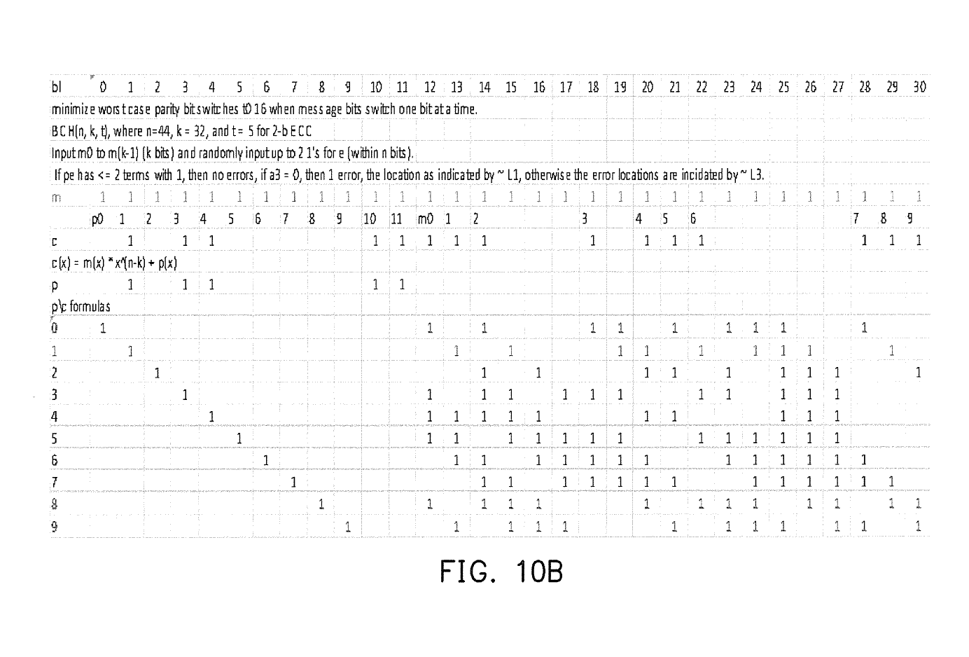

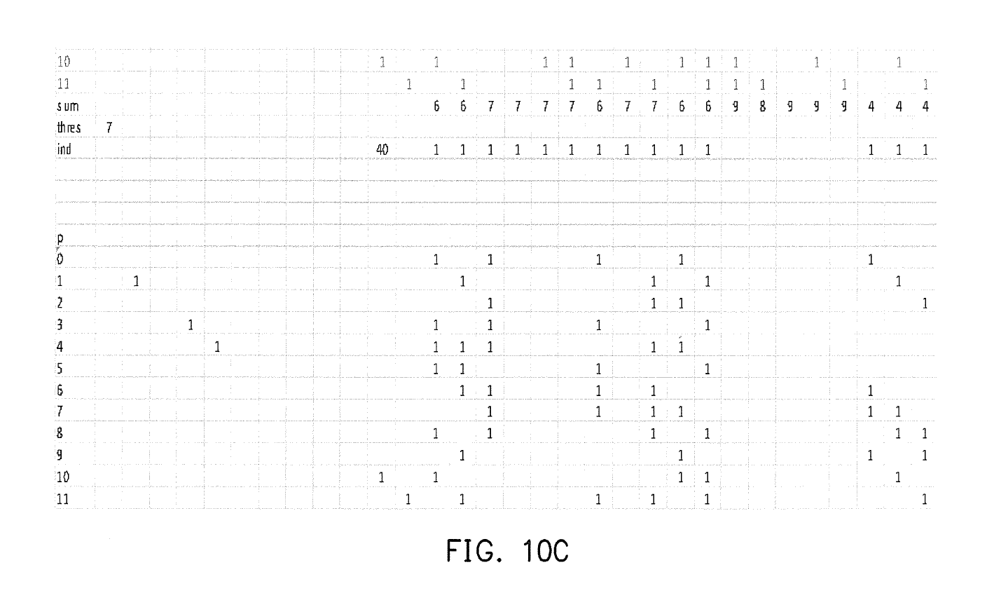

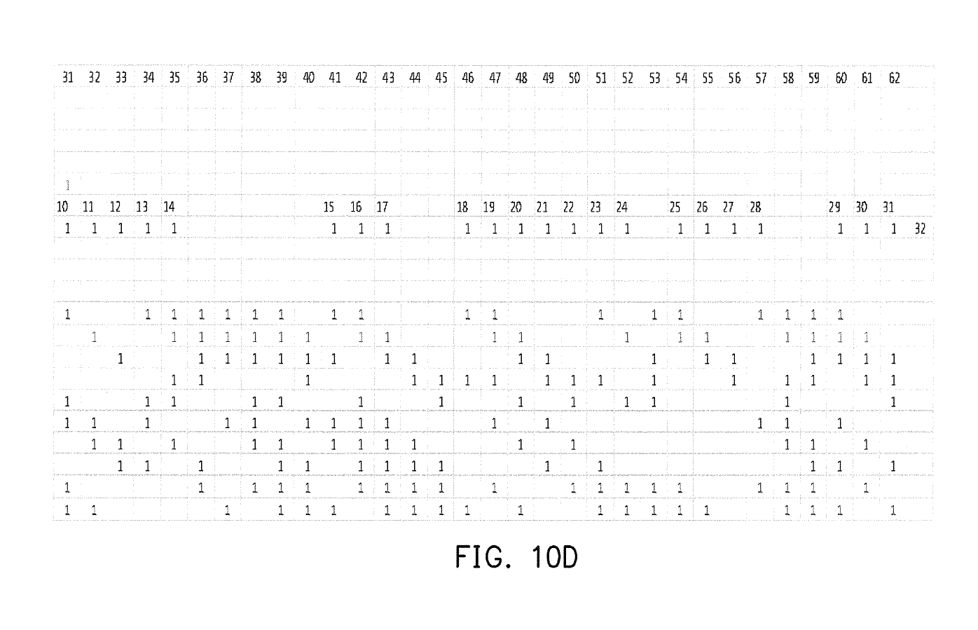

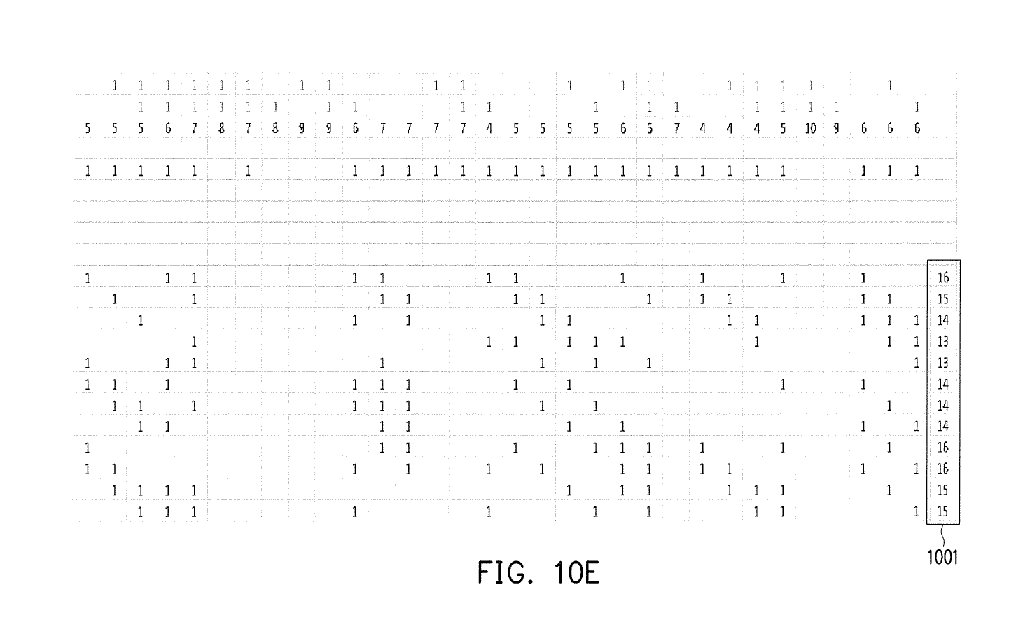

FIG. 10A˜9D is a chart which illustrates a Lien code example of using the proposed method of FIG. 8 in accordance with one of the exemplary embodiments of the disclosure.

In example, the Lien code modified BCH(n, k, t) is used, where n=44, k=32, and t=5 for 2-b ECC. This exemplary embodiment is able to minimize the worst case parity bit flips 1001 when message bits flip one bit at a time. Similar to the previous exemplary embodiment, the parity bits flips and message bits flips are mark as ‘1’ in this chart. In one exemplary embodiment, the encoded codeword could be reordered to have a checkerboard pattern in the manner of the message bits in a sequence of m0-m26, m31, m27-m30 as well as parity bits in a sequence of p0-p4, p8, p6, p7, p5, p10, p9, p11. In another exemplary embodiment, the parity bit flips could be minimized by having the encoded codeword be reordered to have solid “1” in the message bits and/or parity bits as well as by placing some or all message bits at higher bit numbers of the codeword.

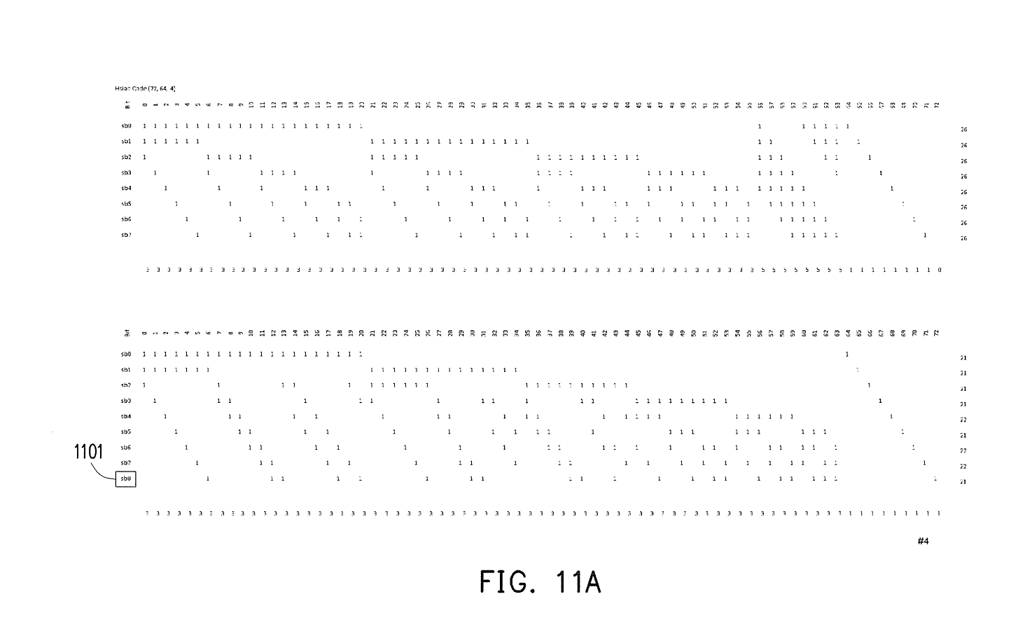

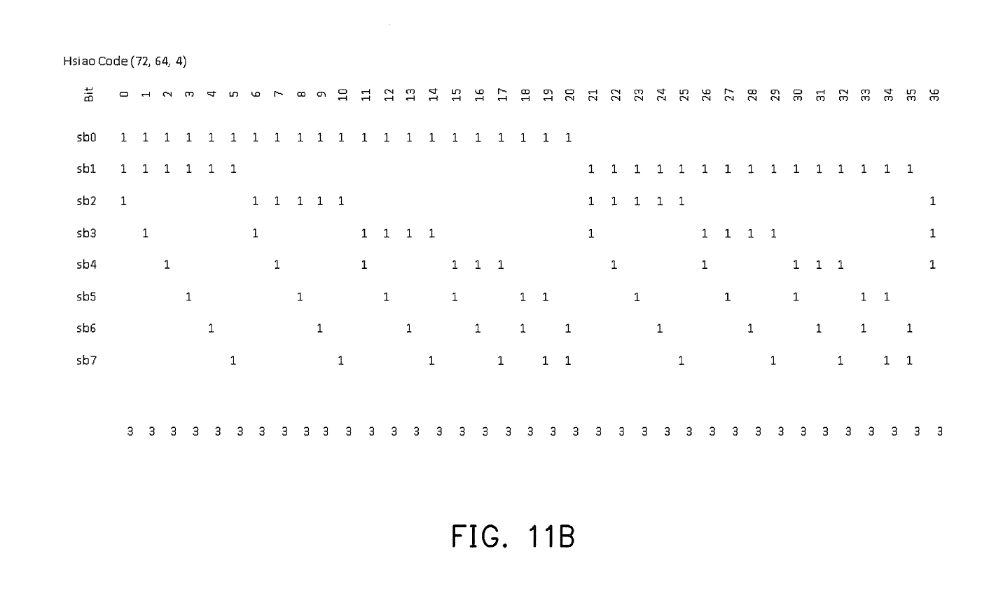

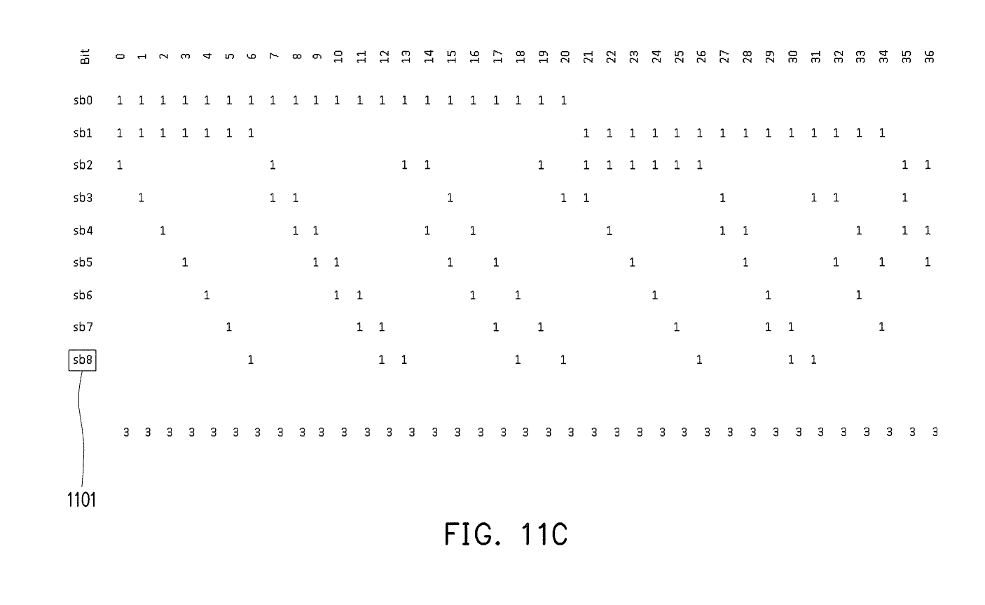

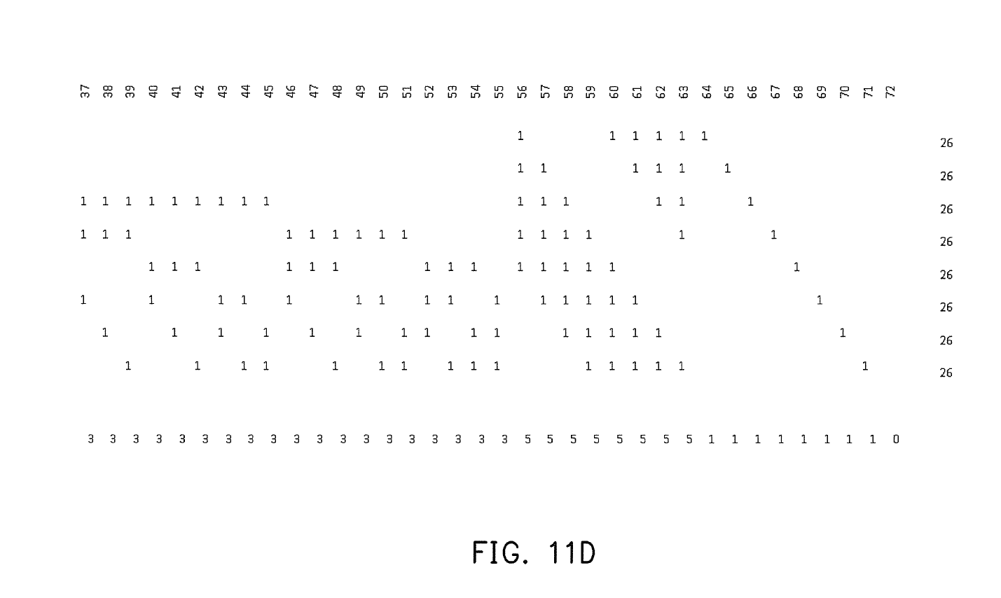

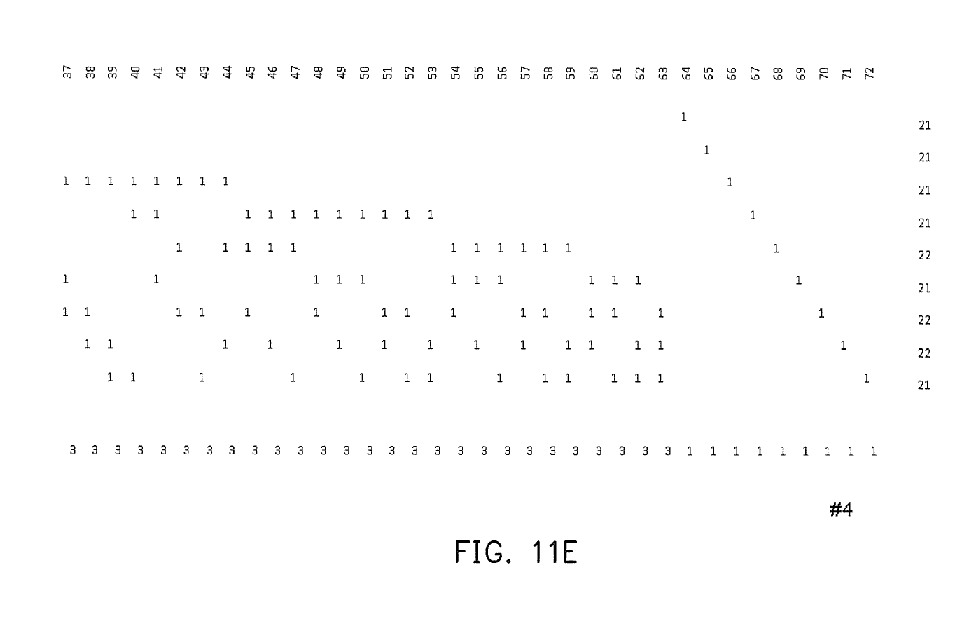

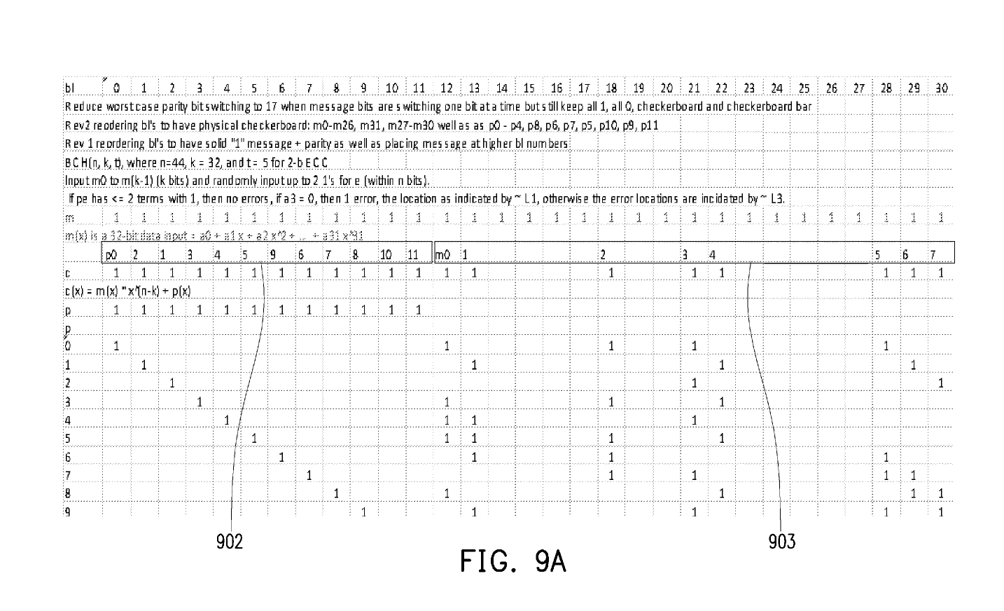

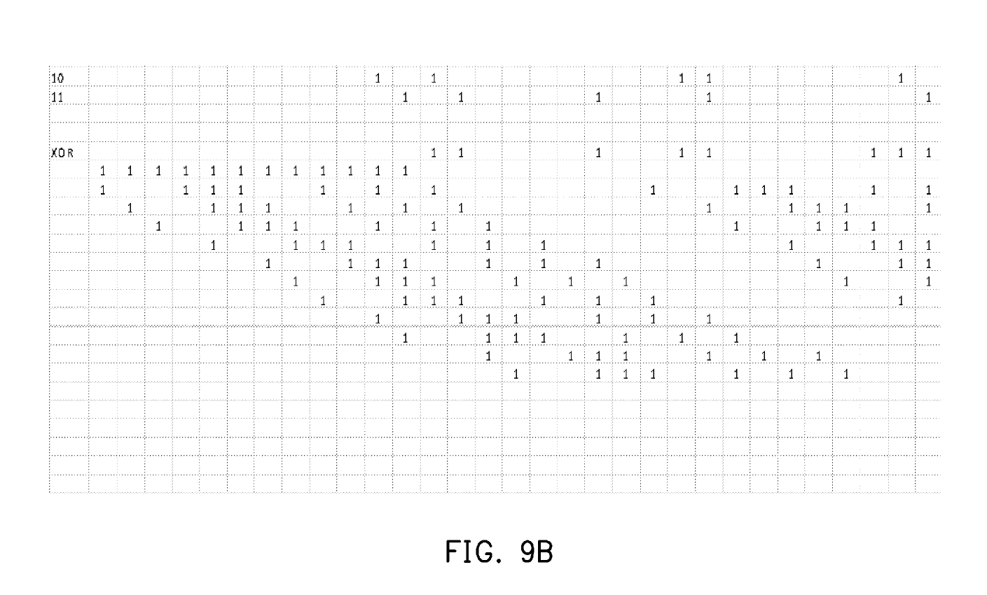

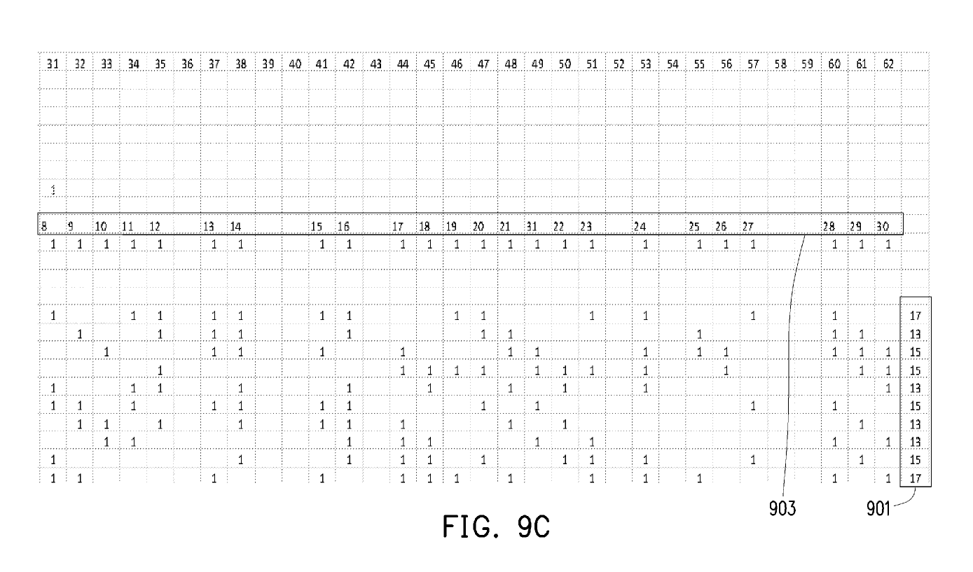

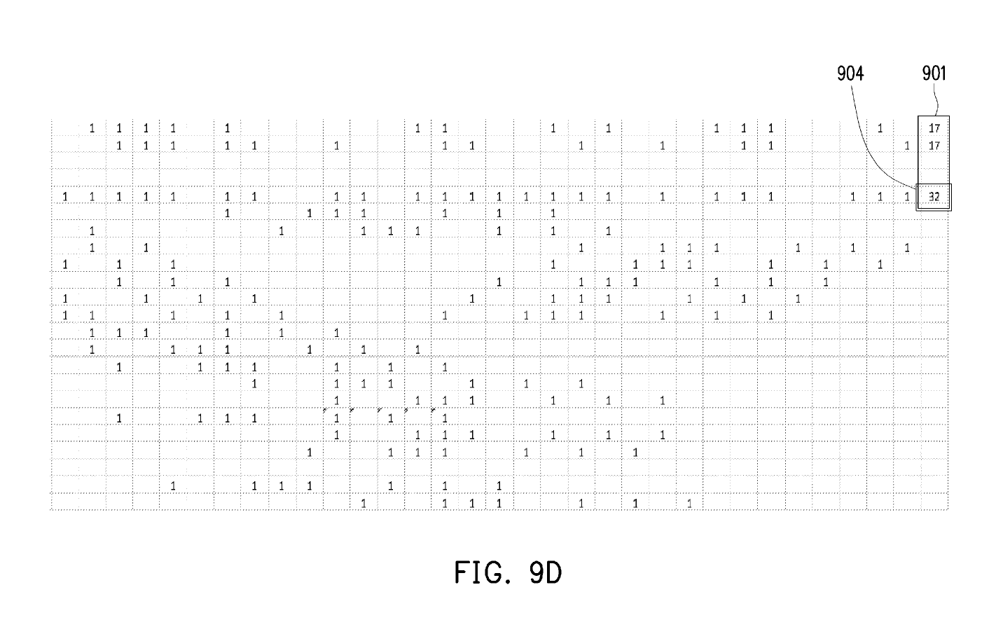

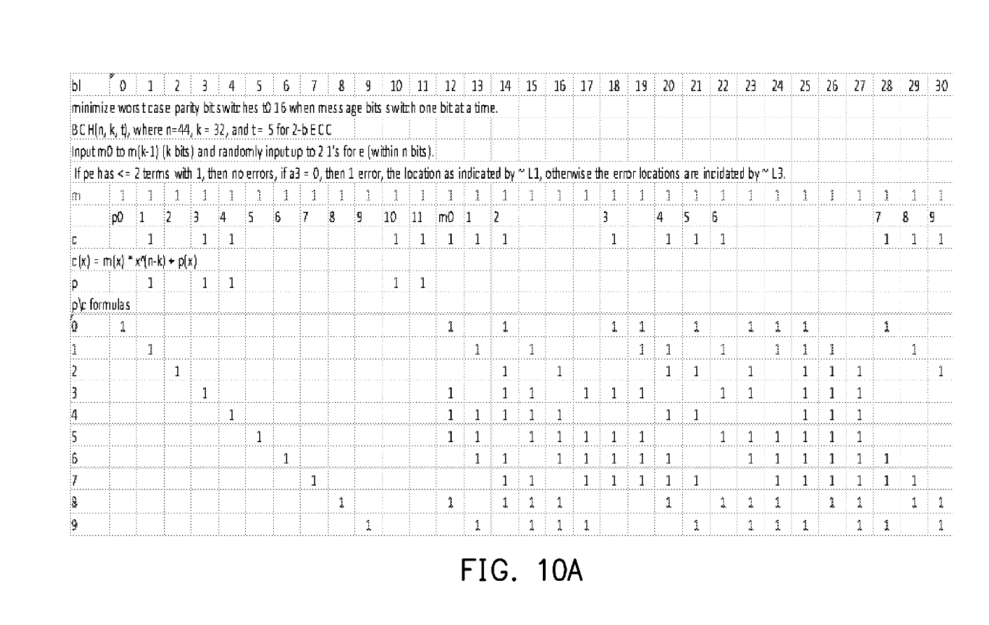

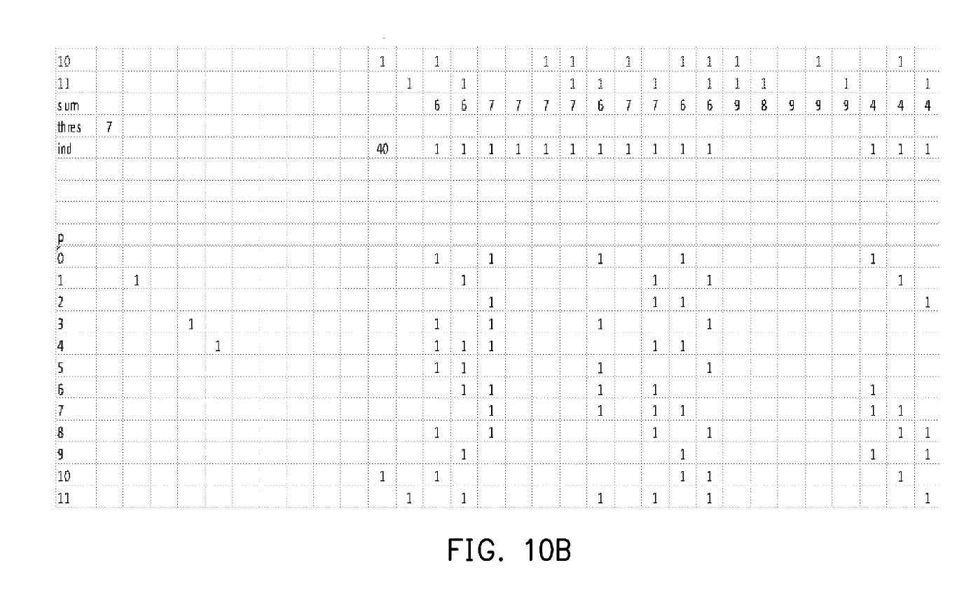

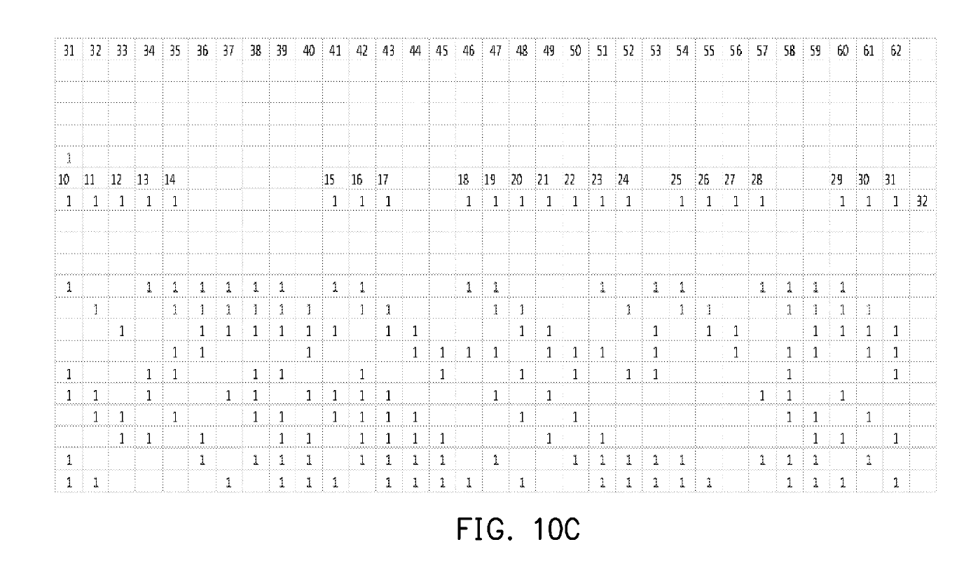

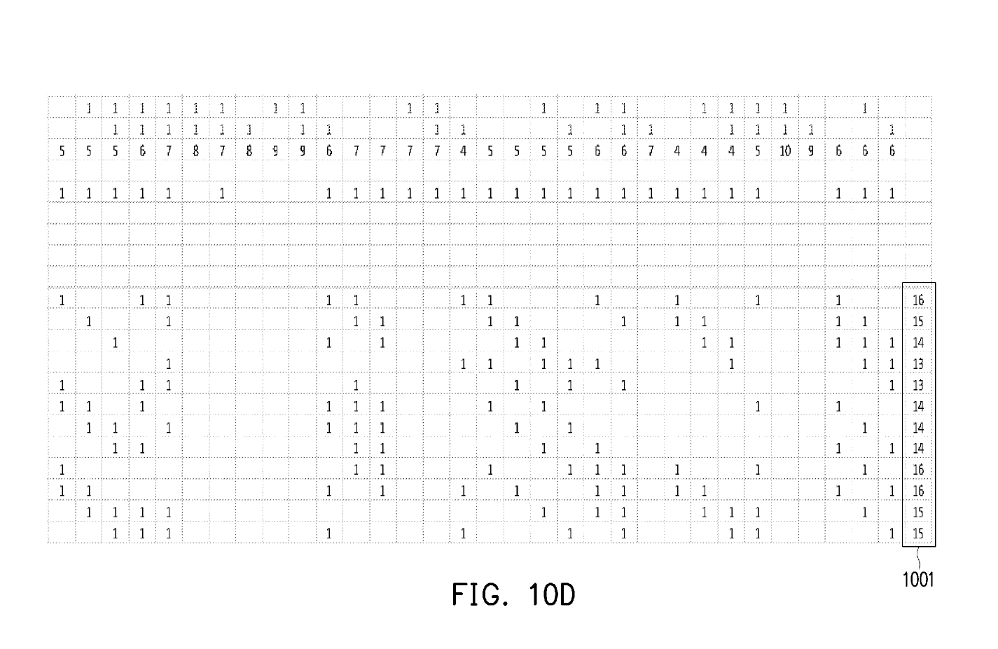

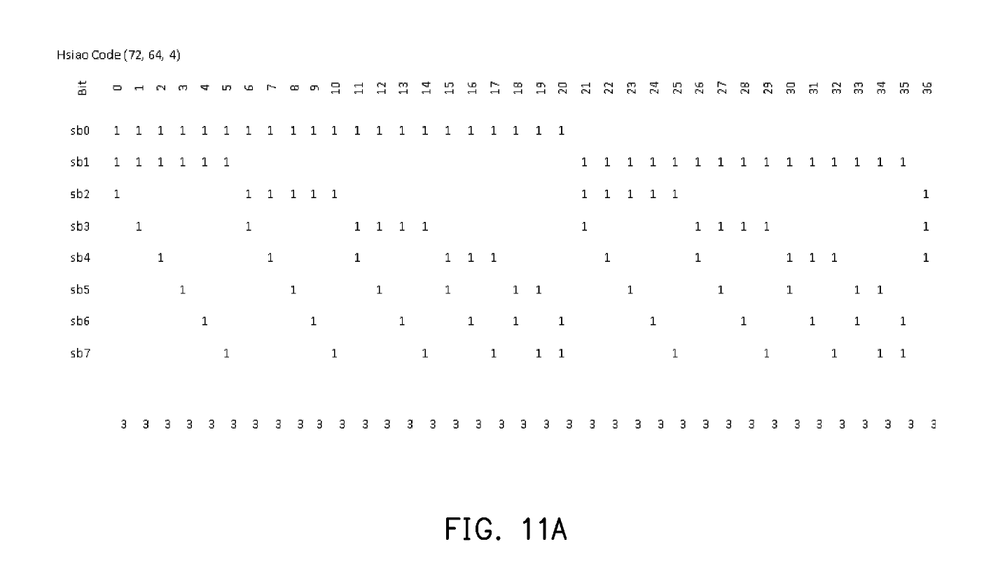

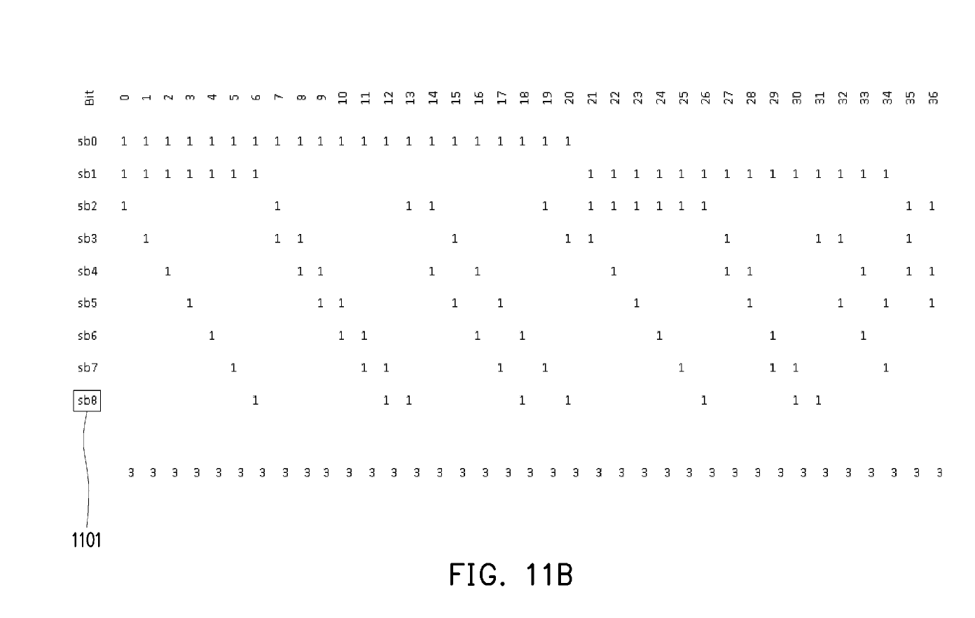

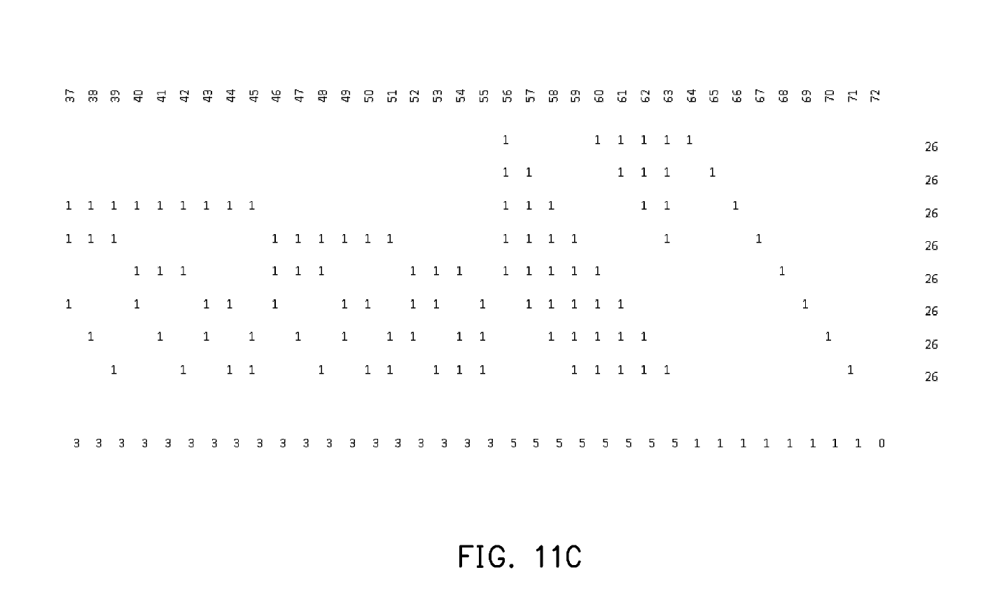

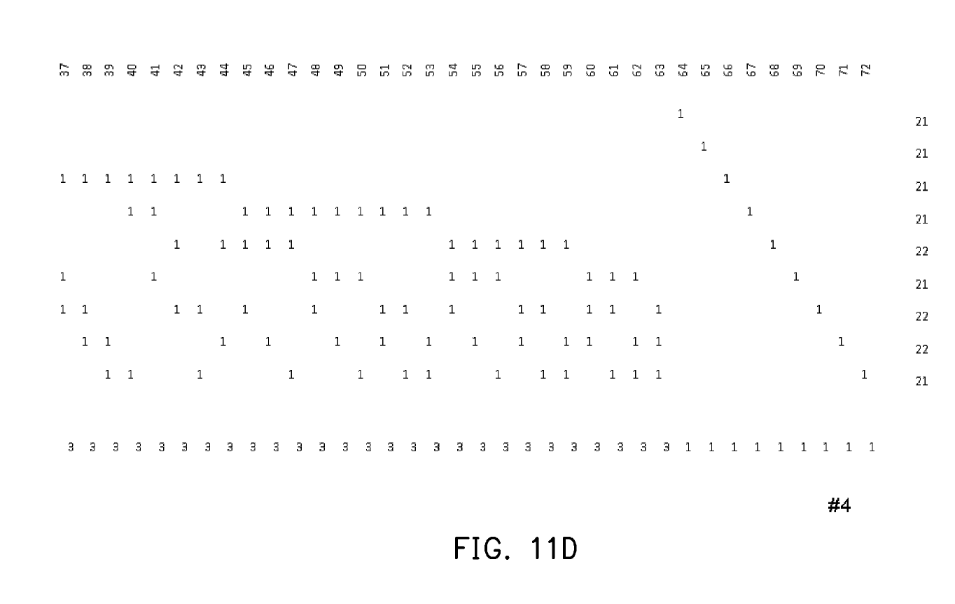

FIG. 11A˜9D illustrates a Hsaio code example of using the proposed method of FIG. 8 in accordance with one of the exemplary embodiments of the disclosure. In this example, a modified Hsiao Code (73, 64, 4) utilized to reduce parity bits' flips by adding one parity bit 1101. With all message bit flips one time, the worst-case number of parity bit flips changes from 26× to 22× and average parity bit flips from 26× to 21.33×

In summary, the disclosure provides a method and an apparatus for implementing an error correcting code used by a memory storage apparatus which would minimize either the average or the maximum number of parity bits flips if every message bit flips once. Similarly the provided method and apparatus would minimize either the average or the maximum number of parity bits' flips if every message bit flips once. Thus, thus the write time and power consumption could be reduced.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A method of implementing an error correcting code (ECC) used by a memory storage apparatus, the method comprising:
receiving a write command comprising a write address and a write data;
reading an existing codeword comprising a predetermined bit sequence;
encoding the write data into a new codeword based on a default ECC;
flipping at least one bit of the new codeword based on a number of bits required to be changed from the existing codeword to the new codeword; and
writing the new codeword, wherein in response to every message bit of the new codeword to be flipped once, either an average or a maximum number of parity bits flips of the new codeword is minimized according to a modified ECC which is based on the default ECC.

2. The method as claimed in claim 1, wherein the modified ECC is modified from a Bose-Chaudhuri-Hocquenghem (BCH) code.

3. The method as claimed in claim 1, wherein the modified ECC is modified from a Hamming code.

4. The method as claimed in claim 1, wherein the modified ECC is modified from a (single-error correcting and double-error detecting) SECDED Hamming code.

5. The method as claimed in claim 1, wherein the modified ECC is modified from a Hsiao code.

6. The method as claimed in claim 1, wherein the modified ECC is modified from a Reed-Solomon code.

7. The method as claimed in claim 1, wherein modified ECC is a Lien code.

8. The method as claimed in claim 1, wherein the modified ECC is used in a counter.

9. The method as claimed in claim 8, wherein the counter is a Gray counter.

10. The method as claimed in claim 1, wherein in response to every message bit of the new codeword to be flipped once, either an average or a maximum number of parity bits flips of the new codeword is minimized according to a modified ECC which is based on the default ECC comprising:
adding parity bits to the default ECC as the modified ECC so that either an average or a maximum number of parity bits flips of the new codeword is minimized.

11. A memory storage apparatus comprising:
a connection interface;
a memory array; and
a memory control circuit which comprises an ECC encoder and is coupled to the connection interface and the memory array, wherein the memory control circuit is configured for:
receiving, through the connection interface, a write command comprising a write address and a write data;
reading an existing codeword comprising a predetermined bit sequence;
encoding the write data into a new codeword based on a default ECC;
flipping at least one bit of the new codeword based on a number of bits required to be changed from the existing codeword to the new codeword; and
writing the new codeword into the memory array, wherein in response to every message bit of the new codeword to be flipped once, either an average or a maximum number of parity bits flips of the new codeword is minimized according to a modified ECC which is based on the default ECC.

12. The apparatus as claimed in claim 11, wherein the modified ECC is modified from a Bose-Chaudhuri-Hocquenghem (BCH) code.

13. The apparatus as claimed in claim 11, wherein the modified ECC is modified from a Hamming code.

14. The apparatus as claimed in claim 11, wherein the modified ECC is modified from a (single-error correcting and double-error detecting) SECDED Hamming code.

15. The apparatus as claimed in claim 11, wherein the modified ECC is modified from a Hsiao code.

16. The apparatus as claimed in claim 11, wherein the modified ECC is modified from a Reed-Solomon Code.

17. The apparatus as claimed in claim 11, wherein modified ECC is a Lien code.

18. The apparatus as claimed in claim 11, wherein the modified ECC is used in a counter.

19. The apparatus as claimed in claim 18, wherein the counter is a Gray counter.

20. The apparatus as claimed in claim 19, wherein the memory control circuit is configured for in response to every message bit of the new codeword to be flipped once, either an average or a maximum number of parity bits flips of the new codeword is minimized according to a modified ECC which is based on the default ECC comprising:
the memory control circuit is configured for in response to every message bit of the new codeword to be flipped once, parity bits are added to the default ECC as the modified ECC so that either an average or a maximum number of parity bits flips of the new codeword is minimized.
